(19) United States
(12) Patent Application Publication
(10) Pub. No.: US 2011/0259840 A1
(43) Pub. Date: Oct. 27, 2011

(54) SEMICONDUCTOR PACKAGE MAGAZINE

(75) Inventors: Jeeyong Park, Kyunggi-Do (KR); Baedoo Kim, Kyunggi-Do (KR); Hyeongno Kim, Kyunggi-Do (KR)

(73) Assignee: ADVANCED SEMICONDUCTOR ENGINEERING, INC., Kaohsiung (TW)

(21) Appl. No.: 12/766,557

(22) Filed: Apr. 23, 2010

(51) Int. Cl. H01L 21/683

(52) U.S. Cl. 211/41.18

(57) ABSTRACT

A magazine rack suitable for holding, carrying, shipping or storing the semiconductor packages is provided. The magazine rack is designed with tiered support bars, so as to help secure the inserted packages in position and provide separation buffer.

### BACKGROUND

1. Field of the Invention

The present invention generally relates to a receptacle for semiconductor packages, and more particularly, to a magazine for holding, carrying or storing semiconductor packages.

2. Description of Related Art

Semiconductor packaging acquires intricate techniques to establish interconnections between different level packages. During the handling and/or testing processes, electronic assembly or semiconductor packages are required to be supported in carriers or magazine containers in order to protect them against damages. Especially for large-sized or thinner packages, special cares are usually required as the wider or thinner packages are more prone to warp or bend, or even slipping out of the magazine container. Hence, it is highly desirable that the electronic or semiconductor packages can be securely supported or held in the magazine containers for quality and cost controls.

### SUMMARY

Accordingly, the present invention is directed to a magazine for holding, storing and/or transporting semiconductor packages. The magazine rack is designed with tiered support bars on the interior surfaces of the sidewalls to further support the inserted packages. Since the received packages are secured by the tiered support bars, the undesirable damages of the packages can be lessened and the quality control of the packages can be improved.

The present invention provides a magazine for semiconductor packages, including a main body, comprising a base, a top and two opposite sidewalls extending from the base and connected to the top. The main body of the magazine is open at two opposite sides other than the two sidewalls. The two sidewalls of the main body comprises a plurality of first support bar pairs and a plurality of second support bar pairs, each of the plurality of the second support bar pairs is located below each of the plurality of the first support bar pairs.

According to an embodiment of the present invention, each of the plurality of the first support bar pairs consists of two first support bars respectively located on interior surfaces of the two sidewalls.

According to an embodiment of the present invention, each of the plurality of the second support bar pairs consists of two second support bars respectively located on interior surfaces of the two sidewalls.

According to an embodiment of the present invention, each first support bar can be substantially coplanar with the interior surface of the sidewall thereon, or protrusive out of the interior surface of the sidewall thereon.

According to an embodiment of the present invention, each second support bar can be protrusive out of the interior surface of the sidewall thereon.

According to an embodiment of the present invention, the two sidewalls comprises a plurality of trench pairs and each of the plurality of the first support bar pairs is defined by each of the plurality of trench pairs.

According to an embodiment of the present invention, each of the plurality of trench pairs consists of two trenches respectively located within the two sidewalls.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic three-dimensional view showing a magazine container according to an embodiment of the present invention.

FIG. 1B is a schematic enlarged cross-sectional view showing a portion of the magazine container of FIG. 1A.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

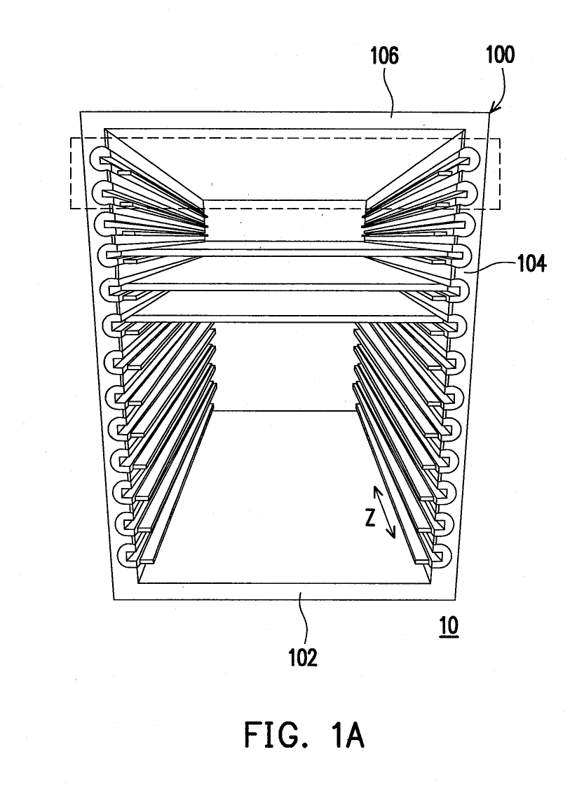

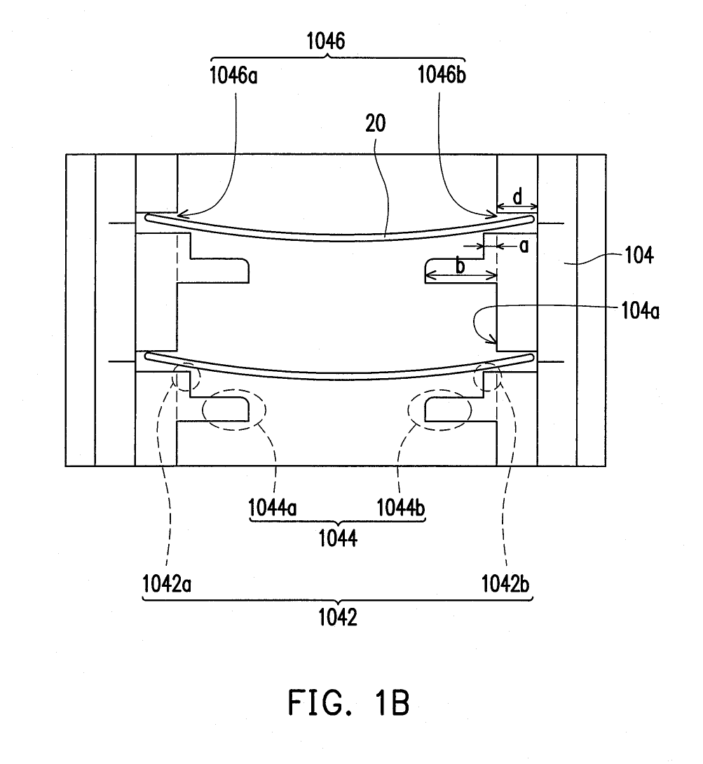

FIG. 1A is a schematic three-dimensional view showing a magazine container according to an embodiment of the present invention. FIG. 1B is a schematic enlarged cross-sectional view showing a portion of the magazine container of FIG. 1A. The magazine container or rack 10 is suitable for holding, buffering, carrying and/or shipping multiple semiconductor packages and mainly comprises a main body 100 of a generally rectangular cross-section. Although the main body 100 of the rectangular cross-section is taken as an example here, it is well understood that the main body 100 can be of various size and cross-sectional configurations, as long as it matches the size and/or the configuration of the inserted packages. The main body 100 has a base 102, two opposite upright sidewalls 104 extending from the base 102, and a top 106 connecting the upright sidewalls 104. The main body 100 is open at the front side and the back side for receiving the inserted packages. The two opposite sidewalls 104 extend along the length direction (Z direction) of the magazine rack 10 and the sidewalls 104 includes a plurality of first support bar pairs 1042 and a plurality of second support bar pairs 1044 thereon. The material of the main body 100 can be a metal material, for example.

The first support bar pairs 1042 are defined by a plurality of parallel trench pairs 1046 formed in the sidewalls 104. Each trench pair 1046 consists of two laterally incurved trenches 1046a, 1046b, formed within the two opposite sidewalls 104 and arranged in alignment. The shape of the trench 1046a/1046b is not limited to the rectangular (cross-sectional shape from the side view) as shown in FIG. 1B, but can be round, oblong, oval or polygonal, for example. Each trench 1046a/1046b extends along the length direction (Z direction), horizontally through (extend from side to side) the upright sidewall 104, and functions as the interior rail or channel of the magazine rack 10. Each first support bar pair 1042 consists two first support bars 1042a, 1042b, each located at the lower side of the trench pair 1046a/1046b. Each second support bar pair 1044 consists of two second support bars 1044a, 1044b, each located below the first support bar 1042a/1042b. Two sides of the package 20 can be inserted or glidingly pushed in to the trench pair 1046 along the length direction and supported by the first support bar pair 1042. The first support bar pair 1042 also helps guiding the insertion of the package 20.

The first support bar pairs 1042 can be simply obtained by laterally cutting into the sidewalls 104 to form the trench pairs 1046 and the lower protruding portion (marked in circle) of each trench 1046a/1046b becomes the first support bar 1042a/1042b, for example. Alternatively, the first support bar pair 1042 can be protruding pieces additionally placed or installed at the lower side of the trench pair 1046, for example. Each first support bar 1042a/1042b can be protrusive, with a distance a, out of the interior surface 104a of the sidewall 104, or each first support bar 1042a/1042b can be substantially coplanar with the interior surface 104a of the sidewall 104 (i.e. distance a is 0). The depth d of the trench 1046a/1046b is about 3.1 mm, while the distance a of the first support bar 1042a/1042b is about 1.0 mm, for example. The pitch, the height or the depth d of the trench 1046a/1046b can be modified according to the specification or the size of the semiconductor package 20. Furthermore, the depth d of the trench 1046a/1046b and/or the distance a of the first support bar can be adjusted so as to provide enough supports for the inserted packages 20 without contacting the active area of the packages 20. The depth d of the trench 1046a/1046b ranges from 2.5 mm to 4.5 mm, while the distance a of the first support bar 1042a/1042b ranges from 0 to 1.0 mm. The semiconductor package 20 can be, for example, large-sized strip or sheet packaged assembly or printed circuit board (PCB).

Each second support bar pair 1044 is located below each first support bar pair 1042 and on the interior surface 104a of the sidewall. The first support bar 1042a/1042b and the beneath second support bar 1044a/1044b are arranged in tiers or as steps. The second support bar 1044a/1044b protrudes from, with a distance b, the interior surface 104a of the sidewall 104. The second support bars 1044a/1044b can provide supplementary supports for the inserted packages 20 and prevent the packages 20 that may slightly warp from falling out of the trenches 1046s/1046b. The distance b of the second support bar 1044a/1044b ranges from 5 mm to 10 mm, preferably can be about 5.4 mm, for example. Compared with the first support bar 1042, the second support bar 1044 may protrude further from the interior surface 104a of the sidewall 104. It is because the second support bars 1044 need to provide extra supports for the warp packages and function as separation buffer to avoid the bent packages from contacting each other, if heavy deformation occurs. Although the second support bar 1044 may protrude more into the space of the magazine rack, the second support bar 1044 should not directly contact the active area of the packages under the normal circumstances, unless the package is drooping or slipped from its position. The second support bars 1044 can be fabricated integrally with the sidewalls 104 or separately installed to the sidewalls 104.

In summary, the magazine rack of the present invention for holding, carrying, shipping or storing the semiconductor packages can provide better supports for the packages. The design of the tiered support bars not only help secure the inserted packages in position but also preclude the possible damages or cracking from the drooping or bent packages.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A magazine for semiconductor packages, comprising:
a main body, comprising a base, a top and two opposite sidewalls extending from the base and connected to the top, wherein the main body is open at two opposite sides other than the two sidewalls, and wherein the two sidewalls comprises a plurality of first support bar pairs and a plurality of second support bar pairs, each of the plurality of the second support bar pairs is located below each of the plurality of the first support bar pairs.

2. The magazine according to claim 1, wherein each of the plurality of the first support bar pairs consists of two first support bars respectively located on interior surfaces of the two sidewalls.

3. The magazine according to claim 1, wherein each of the plurality of the second support bar pairs consists of two second support bars respectively located on interior surfaces of the two sidewalls.

4. The magazine according to claim 1, wherein the two sidewalls comprise a plurality of trench pairs and each of the plurality of the first support bar pairs is defined by each of the plurality of trench pairs.

5. The magazine according to claim 4, wherein each of the plurality of trench pairs consists of two trenches respectively located within the two sidewalls and a depth d of the trench ranges from about 2.5 mm to about 4.5 mm.

6. The magazine according to claim 2, wherein each first support bar is substantially coplanar with the interior surface of the sidewall thereon.

7. The magazine according to claim 2, wherein each first support bar is protrusive, with a distance a, out of the interior surface of the sidewall thereon.

8. The magazine according to claim 7, while the distance a of the first support bar ranges from 0 to about 1.0 mm.

9. The magazine according to claim 3, wherein each second support bar is protrusive, with a distance b, out of the interior surface of the sidewall thereon.

10. The magazine according to claim 9, while the distance b of the second support bar ranges from about 5 mm to about 10 mm.
